(19) United States
(12) Patent Application Publication
(10) Pub. No.: US 2007/0205485 A1
(43) Pub. Date: Sep. 6, 2007

(54) Programmable anti-fuse structures, methods for fabricating programmable anti-fuse structures, and methods of programming anti-fuse structures

(75) Inventors: Louis Lu-Chen Hsu, Fishkill, NY (US); Jack Allan Mandelman, Flat Rock, NC (US); William Robert Tonti, Essex Junction, VT (US); Chih-Chao Yang, Poughkeepsie, NY (US)

Correspondence Address: WOOD, HERRON & EVANS, L.L.P. (IBM), 2700 CAREW TOWER, 441 VINE STREET, CINCINNATI, OH, 45202, US

(73) Assignee: INTERNATIONAL BUSINESS MACHINES CORPORATION, ARMONK, NY (US)

(21) Appl. No.: 11/366,879

(22) Filed: Mar. 2, 2006

(51) Int. Cl. H01L 29/00

(52) U.S. Cl. 257/530

(57) ABSTRACT

Programmable anti-fuse structures for semiconductor device constructions, fabrication methods for forming anti-fuse structures during semiconductor device fabrication, and programming methods for anti-fuse structures. The programmable anti-fuse structure comprises first and second terminals and an anti-fuse layer electrically coupled with the first and second terminals. An electrically-conductive diffusion layer is disposed between the first terminal and the anti-fuse layer. The diffusion layer inhibits diffusion of conductive material from the first terminal to the anti-fuse layer when the anti-fuse structure is unprogrammed, but permits diffusion of the conductive material when a programming voltage is applied between the first and second terminals during operation. Advantageously, the first terminal may be composed of metal and the anti-fuse layer may be composed of a semiconductor. The methods of fabricating the anti-fuse structure do not require an additional lithographic mask but instead rely on damascene process steps used to fabricate interconnection structures for neighboring active devices.

### FIELD OF THE INVENTION

The invention relates generally to semiconductor devices, methods for fabricating semiconductor devices, and methods for operating semiconductor devices and, in particular, to programmable anti-fuse structures, methods of fabricating anti-fuse structures to provide programmable interconnections for semiconductor devices, and methods of programming anti-fuse structures.

### BACKGROUND OF THE INVENTION

The manufacture of integrated circuits typically includes back-end-of-line processing to form metallization layers patterned to interconnect semiconductor device structures fabricated by front-end-of-line processing. Integrated circuit interconnection structures may incorporate anti-fuses that provide normally open fusible links between or within metallization layers. Anti-fuse structures have been primarily used in the semiconductor industry for memory related applications, such as field programmable gate arrays and programmable read-only memories.

Anti-fuses, which consist of an intrinsically high resistance material, may be programmed to exhibit a relatively low resistance that permanently closes a previously open, high resistance circuit path. Specifically, application of a stimulus, such as suitable electrical current passed through the anti-fuse material by application of a large potential difference across the anti-fuse material, operates to significantly reduce the electrical resistance of the anti-fuse material. The lowering of the electrical resistance in the anti-fuse material creates a closed conductive link between or within metallization levels. Once programmed to provide the low-resistance, closed state, the anti-fuse cannot be programmed back to a high-resistance, open state.

With reference to FIG. 1, a conventional anti-fuse structure 10 may include a first conductive feature or terminal 12, a second conductive feature or terminal 14, and an anti-fuse layer 16 of a dielectric material positioned between the first and second terminals 12, 14 in a sandwich construction. The second terminal 14 is embedded in a dielectric layer 18. Before the anti-fuse structure 10 is programmed state, the circuit between the terminals 12, 14 is open because of the high resistance of the anti-fuse layer 16 that electrically isolates the terminals 12, 14 from each other. The anti-fuse structure 10 may be programmed by applying an appropriate voltage between the terminals 12, 14, which causes breakdown of the dielectric material in the anti-fuse layer 16 that forms closed electrically conductive pathways between the terminals 12, 14. The electrically conductive pathways dramatically reduce the electrical resistance of the dielectric material constituting the anti-fuse layer 16 and permanently close the circuit between the terminals 12, 14. The specific programming voltage or current for creating the electrically conductive pathways is a function of the thickness of the anti-fuse layer 16. The closed circuit in the anti-fuse structure 10 may, for example, couple together logic elements of a field programmable gate array.

Conventional anti-fuse structures, such as anti-fuse structure 10, have various deficiencies. For example, at least one additional lithography and etching process is required to fabricate the anti-fuse layer. These additional fabrication steps add cost and complexity to the overall fabrication process. Moreover, conventional anti-fuse structures may require a construction in which a layer of a dielectric or insulating anti-fuse material is disposed between two otherwise disconnected conductive features. The structural requirement limits design flexibility and also enlarges the real estate occupied on the substrate surface area to form conventional anti-fuse structures constructed as a metal-insulator-metal sandwich.

Moreover, dielectric etching during fabrication may introduce non-uniformities in the thickness of the anti-fuse layer. The effect of the thickness non-uniformities is that specific programming voltages required to activate certain anti-fuse structures may be raised to a level above the design programming voltage. Consequently, the effected anti-fuse structures are not activated when the design programming voltage is applied to attempt to close the electrically conductive pathways. Thickness variations in the anti-fuse layer may also cause successfully programmed anti-fuse structures to become deactivated over time, which progressively opens the circuit by increasing the resistance of the anti-fuse material.

What is needed, therefore, are semiconductor device structures with programmable anti-fuses and methods of fabricating anti-fuses to provide programmable interconnections for semiconductor device structures that overcome these and other disadvantages of conventional anti-fuse device structures, fabrication methods, and programming methods.

### SUMMARY OF THE INVENTION

The present invention is generally directed to semiconductor device structures with programmable anti-fuses and methods of fabricating anti-fuses to provide programmable interconnections for semiconductor device structures. In accordance with an aspect of the present invention, a programmable anti-fuse structure comprises a first terminal formed of a conductive material, an electrically-conductive second terminal, and an anti-fuse layer electrically coupled with the first and second terminals. The anti-fuse layer has a first resistance value when the anti-fuse structure is unprogrammed and a second resistance value lower than the first resistance value when the anti-fuse structure is programmed by applying a programming voltage between the first and second terminals. The programmable anti-fuse structure further comprises an electrically-conductive diffusion layer disposed between the first terminal and the anti-fuse layer. The diffusion layer inhibits diffusion of the conductive material from the first terminal to the anti-fuse layer when the anti-fuse structure is unprogrammed. The diffusion layer also permits diffusion of the conductive material from the first terminal to the anti-fuse layer when the programming voltage is applied between the first and second terminals.

In another aspect of the present invention, a method is provided for fabricating a programmable anti-fuse structure from a semiconductor material layer on an insulating substrate. The method comprises defining an electrically isolated anti-fuse region of the semiconductor material layer on the insulating substrate and forming a dielectric layer on the anti-fuse region of the semiconductor material layer. The method further comprises etching a first trench extending through the dielectric layer to the anti-fuse region and lining the first trench with an electrically conductive diffusion layer. The diffusion layer permits transport of the electrically conductive material from a conductive material filling the trench across the diffusion layer and into the semiconductor material layer in the anti-fuse region when a programming voltage is applied across the anti-fuse region.

In yet another aspect of the present invention, a method is provided for programming an anti-fuse structure. The anti-fuse structure comprises first and second terminals that are electrically coupled with a resistive material of the anti-fuse structure. The method comprises transporting conductive material from the first terminal across a diffusion layer separating the resistive material from the first terminal and into the resistive material for reducing the resistance value of the resistive material to close an electrical circuit with the second terminal.

### BRIEF DESCRIPTION OF THE DRAWINGS

The accompanying drawings, which are incorporated in and constitute a part of this specification, illustrate embodiments of the invention and, together with a general description of the invention given above and the detailed description of the embodiments given below, serve to explain the principles of the invention.

FIG. 1 is a diagrammatic view of a portion of a substrate with an anti-fuse construction in accordance with the prior art.

FIGS. 2-13 are diagrammatic cross-sectional views of a portion of a substrate at various fabrication stages of a processing method forming an anti-fuse construction in accordance with an embodiment of the present invention.

FIG. 14 is a diagrammatic top view of the substrate portion of FIG. 13.

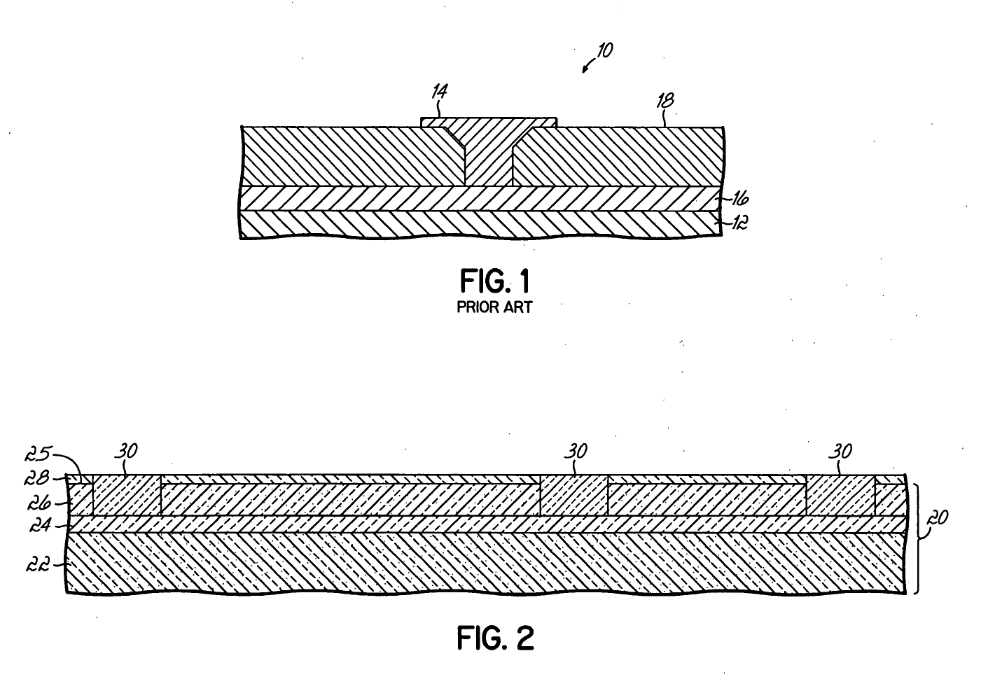

### DETAILED DESCRIPTION

The present invention provides an anti-fuse construction that is activated or programmed by a thermally-accelerated electromigration mechanism. The present invention is advantageously implemented in the design of memory related integrated circuits, such as field programmable gate arrays and programmable read-only memories. The present invention will now be described in greater detail by referring to the drawings that accompany the present application.

With reference to FIG. 2 and in accordance with an embodiment of the present invention, a silicon-on-insulator (SOI) wafer 20 comprises a semiconductor substrate 22, a buried insulator layer 24 formed of an insulating material such as oxide (e.g., SiO₂), and an active device or SOI layer 26 separated from the semiconductor substrate 22 by the intervening buried insulator layer 24. The semiconductor substrate 22 provides mechanical robustness, facilitates handling, and defines an electrically conductive ground plane. The semiconductor substrate 22 and SOI layer 26 are each constituted by single crystal or monocrystalline silicon. The SOI layer 26 may be composed of highly-resistive intrinsic silicon. The SOI layer 26, which is considerably thinner and of higher quality than the semiconductor substrate 22, is electrically isolated from the semiconductor substrate 22 by the buried insulator layer 24. The SOI wafer 20 may be fabricated by any suitable conventional technique, such as a wafer bonding technique or a separation by implantation of oxygen (SIMOX) technique, familiar to a person having ordinary skill in the art. A person having ordinary skill in the art will appreciate that, while the present invention will be described in terms of SOI wafer 20, other layered wafers and chips may benefit from the principles of the present invention.

A hardmask 28 is formed on a top surface 25 of the SOI layer 26. The hardmask 28 may be composed of a dielectric or insulating material, like silicon oxide (SiO₂) grown by exposing the semiconductor material of SOI layer 26 to either a dry oxygen ambient or steam in a heated environment or, alternatively, deposited by a thermal chemical vapor deposition (CVD) process. The material forming hardmask 28 etches selectively to the semiconductor material constituting the SOI layer 26.

A plurality of dielectric-filled shallow trench isolation regions 30 is defined in the SOI layer 26 using a conventional lithography and etching process. Specifically, a resist (not shown) is applied to an upper horizontal surface of the hardmask 28, the resist is exposed to a pattern of radiation characteristic of a shallow trench pattern, the latent pattern transferred into the exposed resist is developed, and then the hardmask 28 is etched using the patterned resist as a template to transfer the shallow trench pattern from the patterned resist to the hardmask 28. Suitable etching processes for transferring the shallow trench pattern include any conventional anisotropic dry etching process, such as reactive-ion etching (RIE) and plasma etching. The chemistry of the etching process, which may be conducted in a single etching step or multiple steps, removes portions of the hardmask 28 visible through the patterned resist and stops vertically on the SOI layer 26. After etching to pattern the hardmask 28 is concluded, the resist is stripped from the hardmask 28 by, for example, plasma ashing or exposure to a chemical stripper.

Another anisotropic dry etching process is then used to transfer the shallow trench pattern from the patterned hardmask 28 into the SOI layer 26. The etching process, which may be conducted in a single etching step or multiple etching steps with different etch chemistries, removes portions of the SOI layer 26 exposed through the patterned hardmask 28 to define a pattern of trenches in a pattern consistent with the shallow trench pattern and stops vertically on the buried insulator layer 24. One suitable etch chemistry comprises a standard silicon RIE process that removes the constituent semiconductor material of SOI layer 26 selective to the dielectric materials constituting the hardmask 28 and buried insulator layer 24.

The isolation regions 30 are defined by filling the trenches of the shallow trench pattern with an insulating or dielectric material. The dielectric material of the isolation regions 30 may be CVD oxide, tetraethylorthosilicate (TEOS), or a high-density plasma (HDP) oxide deposited by any of a number of techniques, such as PECVD, familiar to a person having ordinary skill in the art. Any overfill of dielectric material is removed by planarizing to the top surface of the patterned hardmask 28 with, for example, a chemical-mechanical polishing (CMP) process. An optional high temperature process step may be used to densify a TEOS fill. An active device region 34 of the semiconductor material of SOI layer 26 is bounded by adjacent shallow trench isolation regions 30.

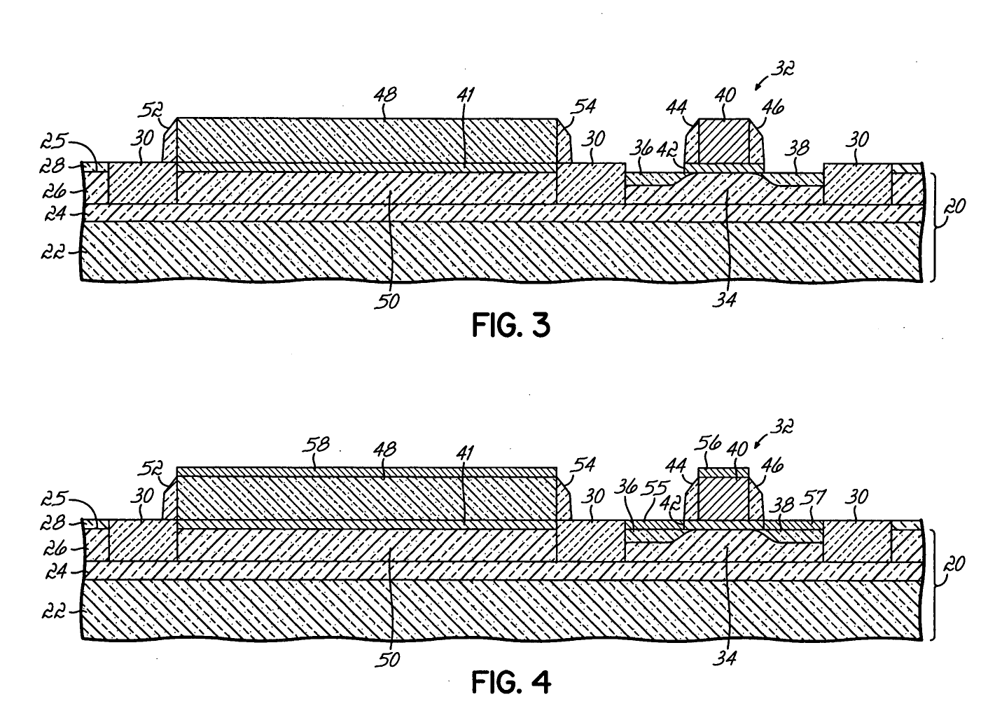

With reference to FIG. 3 in which like reference numerals refer to like features in FIG. 2 and at a subsequent fabrication stage, a metal-oxide-semiconductor (MOS) device 32, such as an N-channel or P-channel transistor, is built using the constituent semiconductor material of SOI layer 26 in the active device region 34. Specifically, the hardmask 28 is selectively removed to expose the active device region 34 of the SOI layer 26. The MOS device 32 includes n-type or p-type diffusions 36, 38 in the semiconductor material of SOI layer 26 representing source and drain regions that flank opposite sides of a channel region in the semiconductor material of SOI layer 26, a gate electrode 40 overlying the channel region, and a gate dielectric 42 electrically isolating the gate electrode 40 from the SOI layer 26.

The diffusions 36, 38 may be formed in the active device region 34 of SOI layer 26 by ion implantation into the constituent semiconductor material of a dopant species having an appropriate conductivity type. The conductor used to form the gate electrode 40 may be, for example, polysilicon, silicide, metal, or any other appropriate material deposited by a CVD process, etc. Advantageously, the conductor constituting gate electrode 40 is doped polysilicon. The gate dielectric 42 may comprise any suitable dielectric or insulating material including, but not limited to, silicon dioxide, silicon oxynitride, a high-k dielectric, or combinations of these dielectrics. The dielectric material constituting gate dielectric 42 may be between about one (1) nm and about ten (10) nm thick, and may be formed by thermal reaction of the semiconductor material of the SOI layer 26 with a reactant, a CVD process, a physical vapor deposition (PVD) technique, or a combination of these methods.

Sidewall spacers 44, 46 are formed that flank the gate electrode 40 of the MOS device 32 and cover the previously bare sidewalls of the gate electrode 40. The sidewall spacers 44, 46 originate from a conformal layer (not shown) of a dielectric material, such as five (5) nm to fifty (50) nm of nitride deposited by CVD, that is shaped by a directional anisotropic etching process that preferentially removes the conformal layer from horizontal surfaces.

The fabrication process forming the gate dielectric 42 also forms a dielectric layer 41 on an anti-fuse layer defined by an anti-fuse region 50 of the SOI layer 26, which is exposed during the process steps forming the MOS device 32. The process step forming the gate electrode 40 applies a sacrificial mask layer 48 of, for example, polysilicon on the anti-fuse region 50 of the SOI layer 26, which is covered by the dielectric layer 41. Similarly, sidewall spacers 52, 54 are formed on the sacrificial mask layer 48 by the process forming sidewall spacers 44, 46 on the gate electrode 40. The sacrificial mask layer 48 protects the anti-fuse region 50 of the SOI layer 26 during the process forming the diffusions 36, 38 so that the semiconductor material of SOI layer 26 in anti-fuse region 50 is not concurrently doped.

With reference to FIG. 4 in which like reference numerals refer to like features in FIG. 3 and at a subsequent fabrication stage, a cap 56 may be formed on an upper surface of the gate electrode 40 between the sidewall spacers 44, 46. The cap 56 may be, for example, self-aligned silicide or salicide formed using a conventional salicidation process, which includes forming a metal, such as titanium (Ti) or nickel (Ni), on the polysilicon of the gate electrode 40, heating the metal/polysilicon stack by, for example, a rapid thermal annealing process to a temperature sufficient to chemically react the polysilicon and metal, and thereafter removing any non-reacted metal. The anti-fuse region 50 of SOI layer 26 is protected by the sacrificial mask layer 48 during the salicidation process. However, the sacrificial mask layer 48 may acquire a surface layer 58 of the constituent silicide of cap 56. Conductive regions 55, 57 of the silicide constituting the cap 56 are also formed on the diffusions 36, 38, respectively, of MOS device 32.

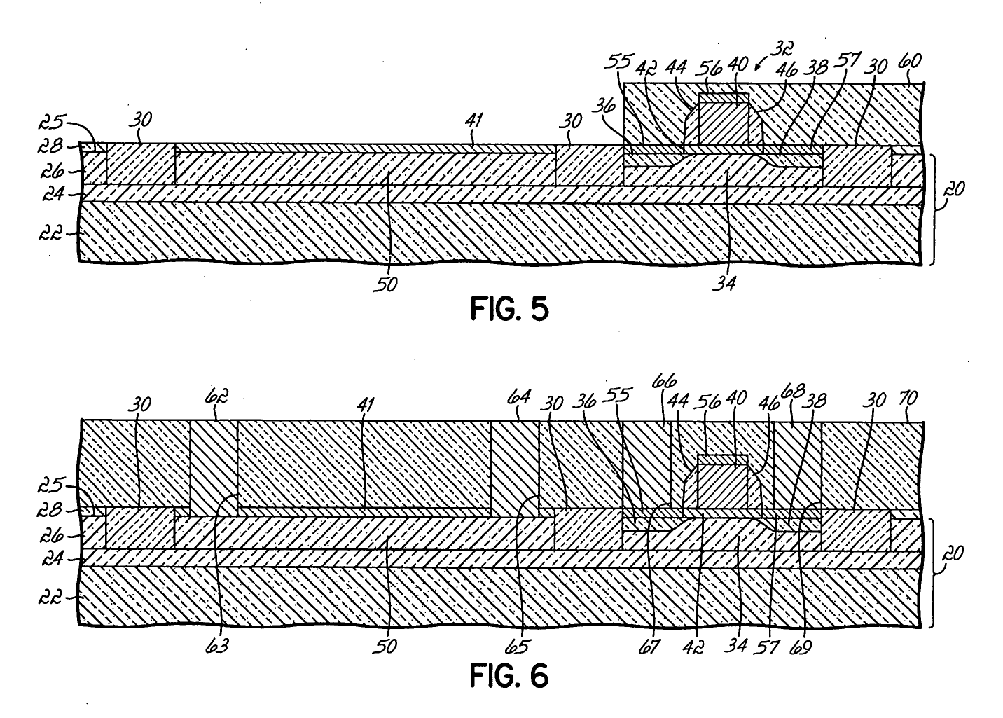

With reference to FIG. 5 in which like reference numerals refer to like features in FIG. 4 and at a subsequent fabrication stage, the sacrificial mask layer 48, sidewall spacers 52, 54, and surface layer 58 are removed to expose the hardmask 28 covering anti-fuse region 50 of the SOI layer 26. If the sacrificial mask layer 48 is composed of polysilicon, removal may be accomplished by chemical etching with an aqueous solution of potassium hydroxide (KOH) stopping on hardmask 28. Active device region 34 of the SOI layer 26, which carries the MOS device 32, is protected during the sacrificial mask layer removal process by a mask 60. The mask 60 may be a low cost photomask, such as a middle ultraviolet (MUV) photolithography mask, because the position of the mask 60 is not rigorously constrained by alignment considerations. After the sacrificial mask layer 48 is removed, the mask 60 is stripped by, for example, plasma ashing or exposure to a chemical stripper to re-expose the active device region 34.

With reference to FIG. 6 in which like reference numerals refer to like features in FIG. 5 and at a subsequent fabrication stage, contact studs 62, 64, 66, 68 of a conductive material are formed in a layer 70 consisting of an electrically insulating or dielectric material. Contact studs 62, 64, which extend vertically through layer 70, constitute terminals that are electrically coupled at spatially separated locations with the semiconductor material of anti-fuse region 50. More specifically, the contact studs 62, 64 are positioned such that a significant portion of the anti-fuse region 50 is between contact studs 62, 64. Contact studs 66, 68, which also extend vertically through layer 70, are electrically coupled with the diffusions 36, 38 of MOS device 32.

Contact studs 62, 64, 66, 68 may be formed using any suitable technique, such as a damascene process in which insulating layer 70 is deposited and patterned to open vias 63, 65, 67, 69. The vias 63, 65, 67, 69 are filled with a suitable conductive material, and excess conductive material is removed from the top surface of insulating layer 70 by a planarization process such as CMP. The vias 63, 65, 67, 69 may be lined with a conductive barrier liner that separates the conductive material from the semiconductor material of SOI layer 26. Suitable materials for contact studs 62, 64, 66, 68 include, but are not limited to, doped polysilicon, silicides, and metals such as gold (Au), aluminum (Al), copper (Cu), molybdenum (Mo), tantalum (Ta), titanium (Ti), or tungsten (W), conformally deposited by evaporation, sputtering, or another known technique.

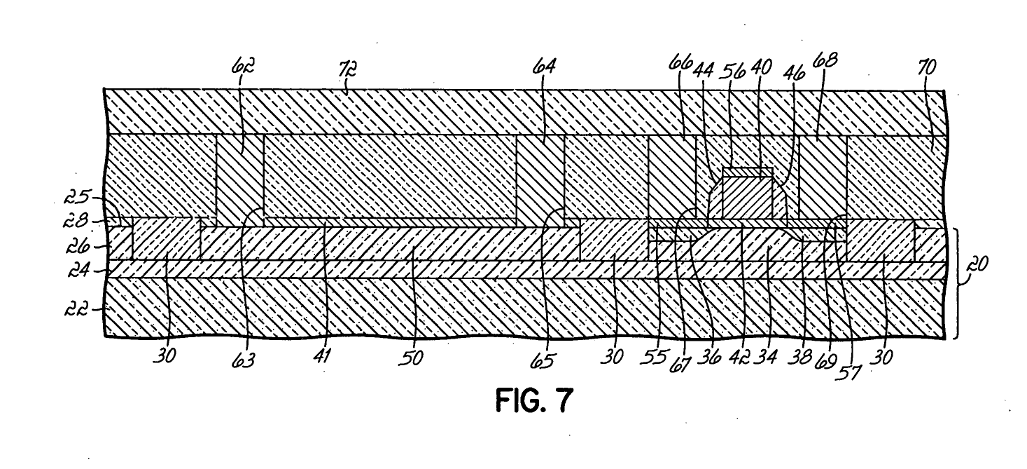

With reference to FIG. 7 in which like reference numerals refer to like features in FIG. 6 and at a subsequent fabrication stage, a layer 72 of an electrically insulating or dielectric material is formed on insulting layer 70. The dielectric material of layer 72 may be characterized by a relative permittivity or dielectric constant less than the dielectric constant of silicon oxide. Generally, such low-k dielectric materials are characterized by a dielectric constant less than about four (4), which represents the dielectric constant of silicon oxide. Candidate low-k materials for insulating layer 72 include, but are not limited to, fluorinated organic polymers such as SiLK® commercially available from Dow Chemical Co. (Midland, Mich.), chemical vapor deposition low-k films such as organosilicate glasses, aerogels, hydrogen silsesquioxane (HSQ), or any combination thereof. The low-k material of insulating layer 72 may be deposited by any of number of well-known techniques including, but not limited to, sputtering, spin-on, or PECVD.

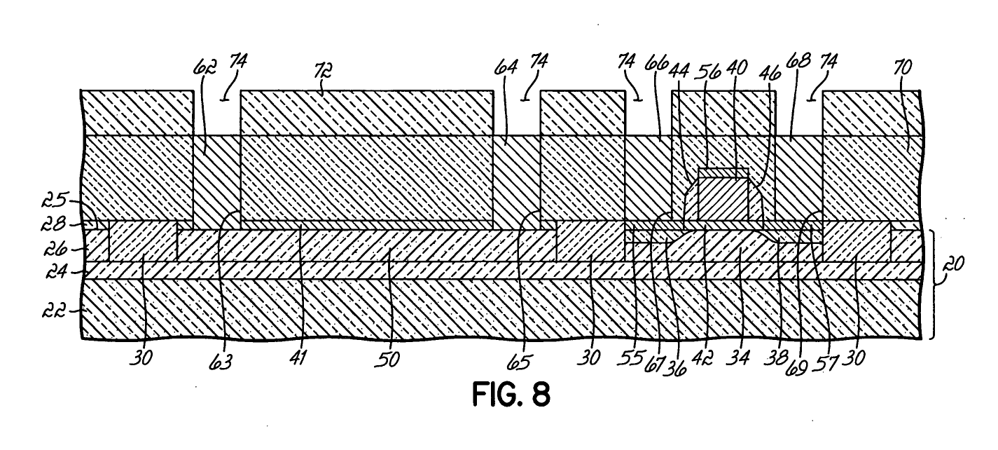

With reference to FIG. 8 in which like reference numerals refer to like features in FIG. 7 and at a subsequent fabrication stage, a plurality of cavities or trenches 74 are defined in insulating layer 72 using a conventional lithography and etching process. Specifically, a resist (not shown) is applied to an upper horizontal surface of the insulating layer 72, the resist is exposed to a pattern of radiation characteristic of a via pattern, the latent pattern transferred into the exposed resist is developed, and then insulating layer 72 is etched using the patterned resist as a template to transfer the via pattern from the patterned resist to the insulating layer 72. Suitable etching processes include any conventional anisotropic dry etching process, such as RIE or plasma etching. The chemistry of the etching process, which may be conducted in a single etching step or multiple steps, removes portions of the hardmask 28 visible through the patterned resist and stops vertically on the insulating layer 72. After etching is concluded, the resist is stripped by, for example, plasma ashing or exposure to a chemical stripper. The trenches 74 extend to the depth of the contact studs 62, 64, 66, 68 and the etching process may advantageously stop on the conductive material of contact studs 62, 64, 66, 68 which etches selective to the dielectric material of insulating layer 72.

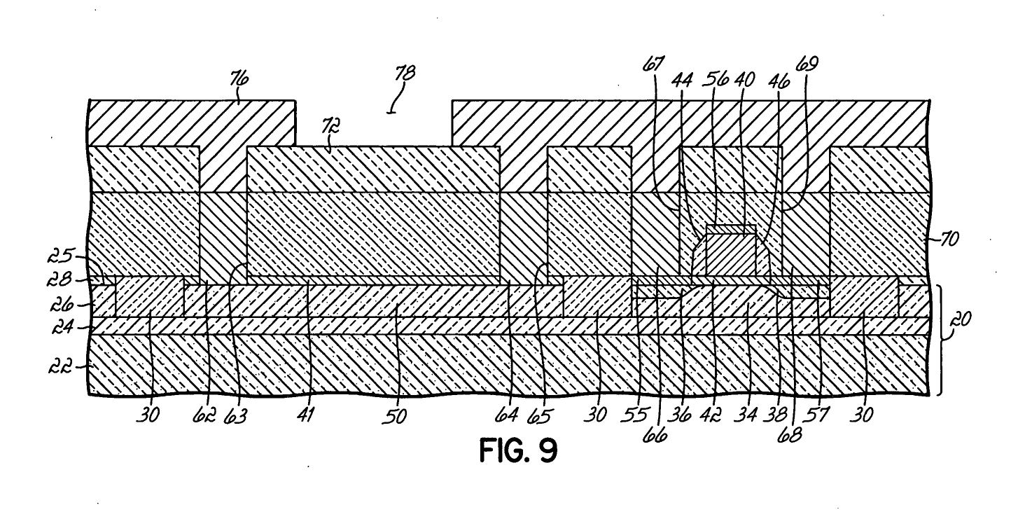

With reference to FIG. 9 in which like reference numerals refer to like features in FIG. 8 and at a subsequent fabrication stage, a mask 76 is applied to an upper horizontal surface of insulating layer 72 and patterned to form an opening 78. The mask 76 may be a resist layer that is patterned by exposing the resist layer to a pattern of radiation and developing the exposed resist to convert the latent pattern into opening 78. The mask 76 may be a low cost photomask, such as a MUV photolithography mask, that is not subject to rigorous alignment constraints.

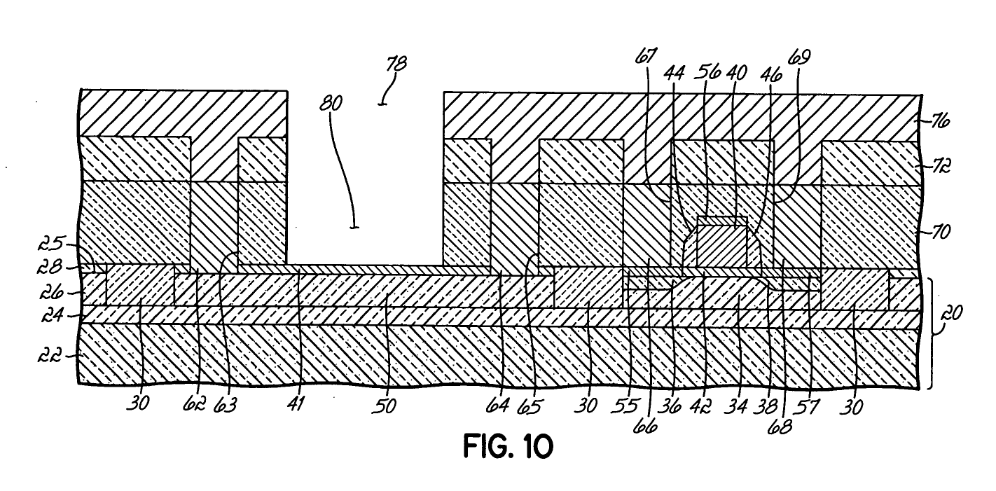

With reference to FIG. 10 in which like reference numerals refer to like features in FIG. 9 and at a subsequent fabrication stage, a trench 80 is etched through the dielectric material of insulating layers 70, 72 using the mask 76. The location of the trench 80 is registered with the location of opening 78 in mask 76 and the depth of the trench 80 is at the horizontal level of dielectric layer 41. Suitable etching processes include any conventional anisotropic dry etching process, such as RIE or plasma etching. The chemistry of the etching process, which may be conducted in a single etching step or multiple steps, removes portions of the insulating layers 70, 72 visible through the mask 76 and stops vertically on the dielectric layer 41. Advantageously, a vertical axis extending centrally through a geometrical center of the open space inside trench 80 may be approximately centered relative to the anti-fuse region 50 and the positions of contact studs 62, 64 may be approximately symmetrical about the location of the trench 80 in the anti-fuse region 50.

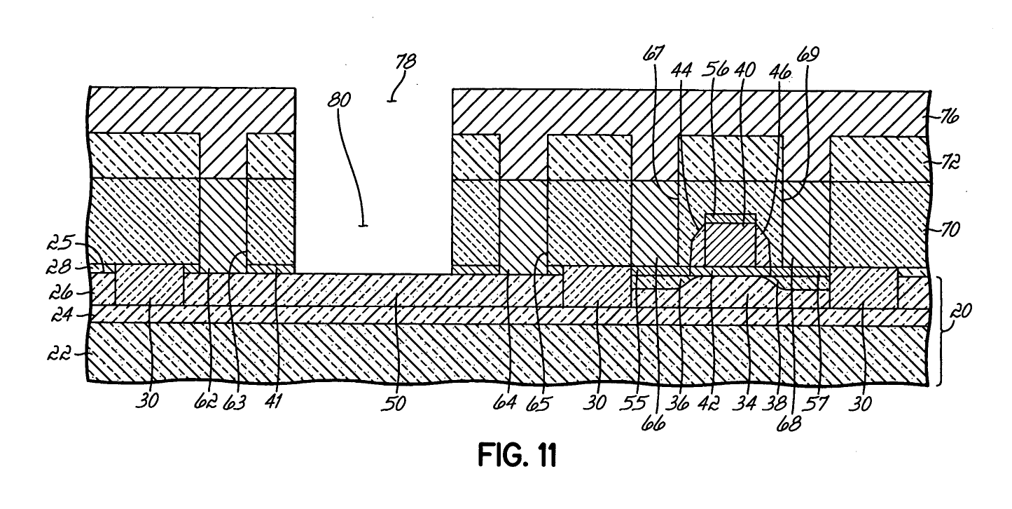

With reference to FIG. 11 in which like reference numerals refer to like features in FIG. 10 and at a subsequent fabrication stage, the depth of the trench 80 is extended vertically through the dielectric layer 41 to the horizontal level of the semiconductor material of SOI layer 26 in anti-fuse region 50. Suitable etching processes include any conventional anisotropic dry etching process, such as RIE or plasma etching, that removes the dielectric material of layer 41 selectively to the semiconductor material of SOI layer 26. The chemistry of the etching process, which may be conducted in a single etching step or multiple steps, removes visible portions of dielectric layer 41 and stops vertically on the SOI layer 26. After the etching process is concluded, mask 76 is stripped by, for example, plasma ashing or exposure to a chemical stripper.

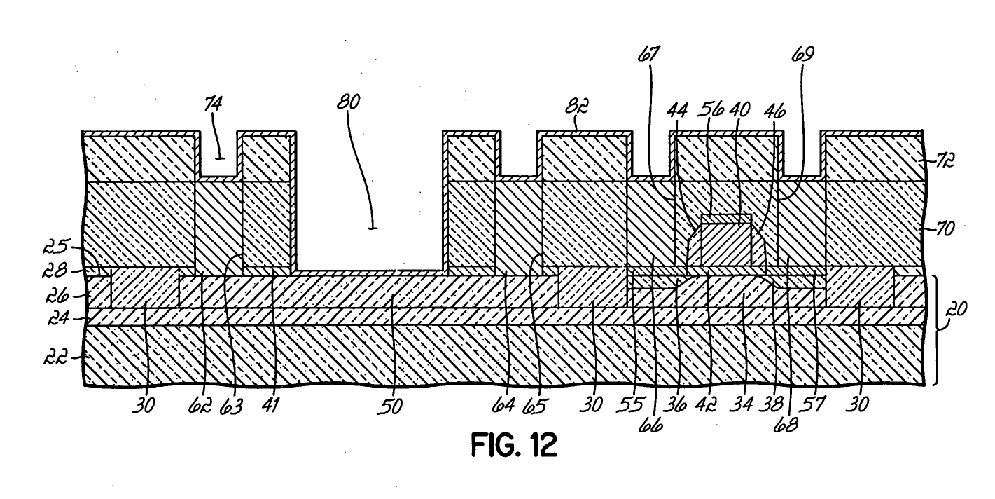

With reference to FIG. 12 in which like reference numerals refer to like features in FIG. 11 and at a subsequent fabrication stage, an electrically-conductive diffusion layer or liner 82 is conformally formed across the substrate 22 and, in particular, defines a thin layer that covers the sidewalls of trenches 74, 80. The liner 82 is formed before depositing an electrically conductive material to fill trenches 74, 80, which prevents at least room temperature diffusion of the conductive material filling trenches 74, 80 into the insulating layers 70, 72. Liner 82 may be formed from an electrically conductive material such as titanium (Ti), tantalum (Ta), tungsten (W), copper (Cu), gold (Au), aluminum (Al), ruthenium (Ru), silver (Ag), and like metals, nitrides of these metals such as titanium nitride (TiN) and tantalum nitride (TaN), and other like materials including combinations thereof. The electrically conductive material constituting the liner 82 is formed with a conventional deposition process such as CVD, PECVD, physical vapor deposition (PVD), atomic layer deposition (ALD), plating, or chemical solution deposition.

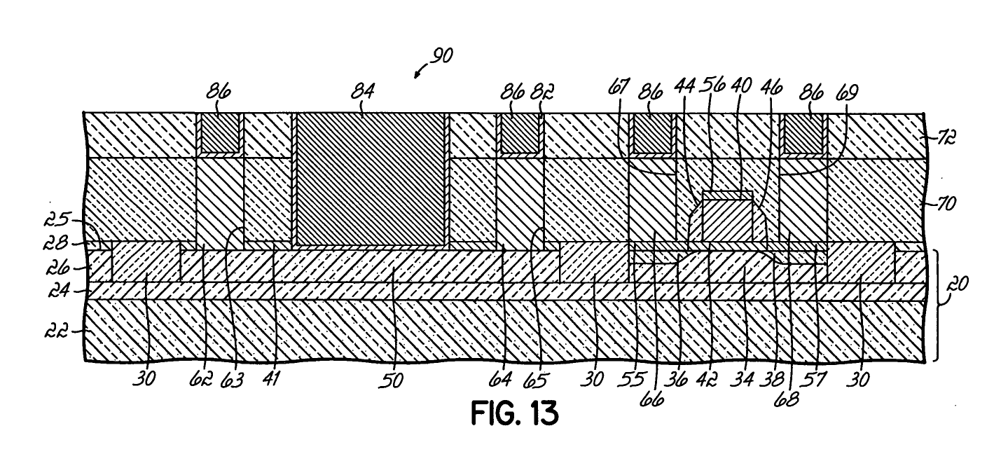

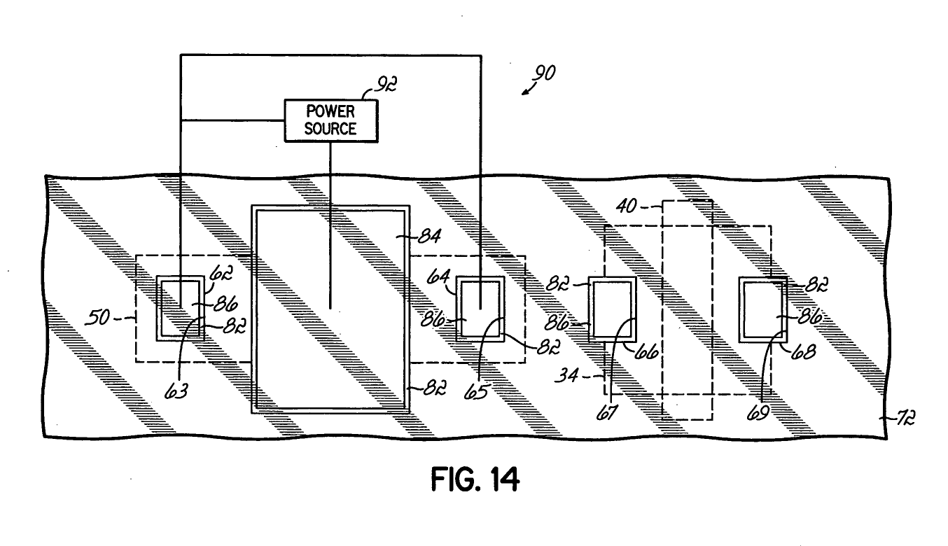

With reference to FIGS. 13 and 14 in which like reference numerals refer to like features in FIG. 12 and at a subsequent fabrication stage, trench 80 (FIG. 12) is filled with an electrode or terminal 84 composed of a conductive material, such as copper (Cu), aluminum (Al), or an alloy. Trenches 74 (FIG. 12) are concurrently filled by the conductive material to define end contacts 86 surrounded by the insulating layer 72. One of the end contacts 86 is in electrical contact with each of the contact studs 62, 64, 66, 68. The terminal 84 and end contacts 86 are formed by deposited a layer (not shown) of the conductive material across substrate 22 and removing extraneous conductor and liner 82 from the top surface of insulating layer 72 using any suitable planarization technique, such as a CMP process, to provide a planarized top surface. The dielectric layer 72 acts as a polishing stop layer. The terminal 84 is formed during the characteristic damascene process forming end contacts 86 without an additional process step or lithographic mask. Terminal 84, which is flanked by the two contact studs 62, 64, is in electrical contact with or otherwise electrically coupled with the anti-fuse region 50 of the SOI layer 26. Advantageously, a vertical axis extending centrally through a geometrical center of terminal 84 may be approximately centered relative to the anti-fuse region 50, and the positions of contact studs 62, 64 may be approximately symmetrical about the location of terminal 84 as a result of the positioning of trench 80.

The anti-fuse region 50 of the SOI layer 26, the contact studs 62, 64 and associated end contacts 86, and the terminal 84 in the aggregate constitute an anti-fuse structure, generally indicated by reference numeral 90. Terminal 84 is electrically coupled with one terminal of a power source 92 (FIG. 14). At least one of the contact studs 62, 64 is electrically coupled with the other terminal of the power source 92 to provide an electrode or terminal complementary to terminal 84 and across which a programming voltage or potential difference may be applied. Advantageously, both of the contact studs 62, 64 are electrically coupled with the other terminal of the power source 92. In this instance, the contact studs 62, 64 and its associated end contact 86 collectively constitute another terminal of the anti-fuse structure 90, which is biased relative to terminal 84 by a programming voltage or potential difference applied between terminal 84 and contact studs 62, 64.

At room temperature and temperatures below the programming temperature, the liner 82 disposed between the terminal 84 and the SOI layer 26 in anti-fuse region 50 substantially prevents diffusion from the terminal 84 to the SOI layer 26. One of the contact studs 62, 64 is electrically coupled with, by its associated end contact 86, for example, one of the diffusions 36, 38 of MOS device 32. As a result, when the anti-fuse structure 90 is programmed, the electrically coupled one of the diffusions 36, 38 is further electrically coupled with the interconnect structure of the integrated circuit.

To program the anti-fuse structure 90, terminal 84 is electrically biased by the power source 92 relative to contact studs 62, 64 by a programming potential difference or voltage. A resulting programming electrical current is directed from the power source 92 to the terminal 84, through the liner 82 to the anti-fuse region 50 of the SOI layer 26, through the highly-resistive semiconductor material of anti-fuse region 50, and toward the flanking contact studs 62, 64. Electrical current flowing through the anti-fuse region 50 causes the highly-resistive constituent semiconductor material of the anti-fuse region 50 to heat. At a characteristic programming temperature, atoms of the constituent conductive material of terminal 84 are transported by diffusion from the terminal 84 across the thickness of the liner 82 and into the anti-fuse region 50. The failure of liner 82 as an effective diffusion barrier may occur when the anti-fuse structure 90 is heated by a programming voltage to a programming temperature in the range of about 400° C. to about 800° C., which is contingent upon material type and thickness among other factors. For example, at a programming temperature of approximately 600° C., copper in terminal 84 will be transported across tantalum in the liner 82 and penetrate as a conductivity-enhancing impurity into the anti-fuse region 50. Both contacts 62, 64 may be advantageously electrically biased to the same potential with respect to the terminal 84, assuring that breakdown of the liner 82 is symmetrical in the horizontal plane relative to a central vertical plane of the anti-fuse region 50 of the SOI layer 26.

Advantageously, the terminal 84 is negatively biased with respect to the contact studs 62, 64, which produces a directional electron flux directed across the interface between the terminal 84 and liner 82 and into the anti-fuse region 50 of the SOI layer 26. Although not wishing to be bound by theory, the transport of conductive material from the terminal 84 across the liner 82 to the anti-fuse region 50 is believed to be enhanced by an electromigration mechanism familiar to persons having ordinary skill in the art. Specifically, the directionality of the current flow arising from the negative biasing of the terminal 84 relative to the contact studs 62, 64 results in momentum transfer between the electrons in the current and the atoms of the conductor constituting terminal 84. The elevated temperature of the anti-fuse structure 90, which precipitates diffusion or migration of atoms of the conductor from the terminal 84 through the liner 82, may also accelerate the electromigration process.

At or above the characteristic programming temperature, the resistance value of the semiconductor material of the anti-fuse region 50 drops dramatically in response to the presence of the atomic concentration of conductor atoms originating from terminal 84. Specifically, the semiconductor material of the anti-fuse region 50 has a first resistance value when the anti-fuse structure 90 is unprogrammed and a second resistance value lower than the first resistance value when the anti-fuse structure 90 is programmed. The reduced resistance transforms the previously open anti-fuse structure 90 to a closed condition. The decrease in the resistance experienced by the semiconductor material in the anti-fuse region 50 of anti-fuse structure 90 may be as much as two to four orders of magnitude. The isolation regions 30 flanking the anti-fuse region 50 and the buried insulator layer 24 mitigate heat transfer to the MOS device 32, which serves to minimize thermal effects of programming on the MOS device 32.

Additional active device regions 34 and anti-fuse regions 50 are distributed across the substrate 22, as understood by a person having ordinary skill in the art. Each active device region 34 includes a MOS device similar to MOS device 32 and an anti-fuse structure similar to anti-fuse structure 90.

The anti-fuse structure 90 of the present invention is implemented with a reduced number of lithography and etching process steps in comparison with conventional processes for forming anti-fuse constructions. The anti-fuse fabrication process of the present invention is compatible with current metal-oxide-semiconductor (MOS) process flows and does not require extra masking steps to implement. In particular, the terminal 84 of the anti-fuse structure 90 is formed concurrently with the end contacts 86 as part of a damascene process. The process compatibility lowers overall process costs in comparison with conventional processes for forming anti-fuse constructions. The anti-fuse construction of the present invention is programmable by diffusion and optional thermally-accelerated electromigration, which differs from conventional anti-fuse constructions that are voltage programmed. As a result, the anti-fuse construction of the present invention may differ from the conventional sandwich structure that disposes a layer of anti-fuse material between two disconnected conductive features. Accordingly, the anti-fuse construction of the present invention is more compact, which improves flexibility in circuit design and provides a size advantage in comparison with conventional anti-fuse constructions.

References herein to terms such as “vertical”, “horizontal”, etc. are made by way of example, and not by way of limitation, to establish a frame of reference. The term “horizontal” as used herein is defined as a plane parallel to the top surface 25 of SOI layer 26, regardless of its actual spatial orientation. The term “vertical” refers to a direction perpendicular to the horizontal, as just defined. Terms, such as “on”, “above”, “below”, “side” (as in “sidewall”), “higher”, “lower”, “over”, “beneath” and “under”, are defined with respect to the horizontal plane. It is understood that various other frames of reference may be employed for describing the present invention without departing from the spirit and scope of the present invention.

The fabrication of the semiconductor structure herein has been described by a specific order of fabrication stages and steps. However, it is understood that the order may differ from that described. For example, the order of two or more fabrication steps may be switched relative to the order shown. Moreover, two or more fabrication steps may be conducted either concurrently or with partial concurrence. In addition, various fabrication steps may be omitted and other fabrication steps may be added. It is understood that all such variations are within the scope of the present invention. It is also understood that features of the present invention are not necessarily shown to scale in the drawings.

While the present invention has been illustrated by a description of various embodiments and while these embodiments have been described in considerable detail, it is not the intention of the applicants to restrict or in any way limit the scope of the appended claims to such detail. Additional advantages and modifications will readily appear to those skilled in the art. Thus, the invention in its broader aspects is therefore not limited to the specific details, representative apparatus and method, and illustrative example shown and described. Accordingly, departures may be made from such details without departing from the spirit or scope of applicants' general inventive concept.

What is claimed is:

1. A programmable anti-fuse structure on a substrate, comprising:
a first terminal formed of a conductive material;
an electrically-conductive second terminal;
an anti-fuse layer electrically coupled with said first and second terminals, said anti-fuse layer having a first resistance value when said anti-fuse structure is unprogrammed and a second resistance value lower than said first resistance value when said anti-fuse structure is programmed by applying a programming voltage between said first and second terminals; and
an electrically-conductive diffusion layer disposed between said first terminal and said anti-fuse layer, said diffusion layer inhibiting diffusion of said conductive material from said first terminal to said anti-fuse layer when said anti-fuse structure is unprogrammed, and said diffusion layer permitting diffusion of the conductive material from said first terminal to said anti-fuse layer when said programming voltage is applied between said first and second terminals.

2. The programmable anti-fuse structure of claim 1 further comprising:
a dielectric layer overlying said anti-fuse layer, said first and second terminals extending through said dielectric layer to said anti-fuse layer.

3. The programmable anti-fuse structure of claim 2 further comprising:
an active device region of a semiconductor material electrically isolated from said anti-fuse layer; and
a metal-oxide-semiconductor device with a source region and a drain region formed as diffusions in said semiconductor material of said active device region.

4. The programmable anti-fuse structure of claim 3 further comprising:
a contact electrically coupled with said source or said drain, at least a portion of said contact extending through said dielectric layer to said active device region.

5. The programmable anti-fuse structure of claim 1 further comprising:
dielectric-filled isolation regions arranged laterally about said anti-fuse layer.

6. The programmable anti-fuse structure of claim 5 further comprising:
an insulating layer contacted by said isolation regions, said anti-fuse layer being disposed between said insulating layer and said first and second terminals.

7. The programmable anti-fuse structure of claim 5 further comprising:
an active device region of a semiconductor material separated laterally from said anti-fuse layer by one of said isolation regions; and
a metal-oxide-semiconductor device with a source region and a drain region formed as diffusions in said semiconductor material of said active device region.

8. The programmable anti-fuse structure of claim 7 further comprising:
a contact electrically coupled with said source or said drain, at least a portion of said contact being formed from the conductive material of the first terminal.

9. The programmable anti-fuse structure of claim 1 wherein said anti-fuse layer comprises a semiconductor material, said conductive material of said first terminal comprises a metal, and said diffusion layer is effective for inhibiting diffusion of the metal from said first terminal to said anti-fuse layer when said anti-fuse structure is unprogrammed.

10. The programmable anti-fuse structure of claim 1 further comprising:
an electrically-conductive third terminal electrically coupled with said anti-fuse layer, said second and third terminals being positioned substantially symmetrically about a central axis of said first terminal.

11. A method of fabricating a programmable anti-fuse structure from a semiconductor material layer on an insulating substrate, the method comprising:
defining an electrically isolated anti-fuse region of the semiconductor material layer on the insulating substrate;
forming a dielectric layer on the anti-fuse region of the semiconductor material layer;
etching a first trench extending through the dielectric layer to the anti-fuse region;
lining the first trench with an electrically conductive diffusion layer that permits transport of a conductor from a conductive material filling the trench across the conductive diffusion layer and into the semiconductor material layer in the anti-fuse region when a programming voltage is applied across the anti-fuse region; and
filling the first trench with the conductive material.

12. The method of claim 11 wherein defining the electrically isolated anti-fuse region further comprises:
forming dielectric-filled second trenches in the semiconductor material layer about the anti-fuse region that extend through the semiconductor material layer to the insulating substrate.

13. The method of claim 12 further comprising:
defining an active device region of the semiconductor material layer separated from the anti-fuse region by one of the dielectric-filled second trenches;
doping the active device region of the semiconductor material layer to form a source and a drain of a semiconductor device; and
protecting the anti-fuse region while the active device region is doped.

14. The method of claim 13 wherein protecting the anti-fuse region further comprises:
depositing a conductor on the active device region to form a gate electrode for the semiconductor device;
depositing the conductor on the anti-fuse region concurrently with forming the gate electrode to define a sacrificial protective layer on the anti-fuse region; and
removing the sacrificial protective layer from the anti-fuse region after the active device region is doped.

15. The method of claim 13 further comprising:
forming the dielectric layer on the active device region of the semiconductor material layer;
forming cavities in the dielectric layer overlying the active device region; and
masking the cavities while forming the first trench.

16. The method of claim 11 further comprising:
etching a second trench in the dielectric layer overlying the active device region extending to a depth shallower than the first trench so that the second trench does not contact the anti-fuse region of the semiconductor material layer; and
masking the second trench while forming the first trench.

17. The method of claim 16 wherein masking the second trench further comprises:
applying a photomask that is not subject to rigorous alignment constraints for protecting the second trench.

18. The method of claim 17 further comprising:
stripping the photomask before lining the first trench so that the diffusion layer further lines the second trench.

19. The method of claim 16 wherein filling the first trench with the conductive material further comprises:
filling the second trench with the conductive material concurrently with filling the first trench.

20. The method of claim 17 wherein filling the second trench further comprises:
depositing a conformal layer of the conductive material across the dielectric layer that fills the first and second trenches; and
removing extraneous portions of the conformal layer from the dielectric layer in a planarization process to leave residual inlaid conductive material in the first and second trenches.

21. A method of programming an anti-fuse structure having a first terminal and a second terminal that are electrically coupled with a resistive material of the anti-fuse structure, the method comprising:
transporting conductive material from the first terminal across a diffusion layer separating the resistive material from the first terminal and into the resistive material for reducing the resistance value of the resistive material to close an electrical circuit with the second terminal.

22. The method of claim 21 wherein transporting conductive material further comprises:
heating the resistive material to elevate the anti-fuse structure to a programming temperature sufficient to thermally diffuse conductive material from the first terminal across the diffusion layer and into the resistive material.

23. The method of claim 22 wherein heating the resistive material further comprises:
applying a programming voltage between the first and second terminals sufficient to heat the resistive material.

24. The method of claim 21 wherein transporting conductive material further comprises:
electrically biasing the first and second terminals such that an electron current is directed from the first terminal through the resistive material to the second terminal.

25. The method of claim 24 wherein electrically biasing the first and second terminals further comprises:
applying a voltage between the first and second terminals sufficient to heat the resistive material to elevate the anti-fuse structure to a temperature sufficient to thermally diffuse conductive material from the first terminal across the diffusion layer to the anti-fuse layer such that the heating cooperates with the electron current to transport conductive material into the resistive material.
